(19) United States
(12) Patent Application Publication
(10) Pub. No.: US 2008/0191299 A1
(43) Pub. Date: Aug. 14, 2008

(54) MICROLENSES FOR IRREGULAR PIXELS

(76) Inventor: Christopher Parks, Rochester, NY (US)

Correspondence Address: Frank Pincelli;Patent Legal Staff, Eastman Kodak Company, 343 State Street, Rochester, NY, 14650-2201, US

(21) Appl. No.: 11/748,573

(22) Filed: May 15, 2007

Related U.S. Application Data
(60) Provisional application No. 60/889,326, filed on Feb. 12, 2007.

(51) Int. Cl. H01L 31/0232

(52) U.S. Cl. 257/432; 257/E31.127

(57) ABSTRACT

A digital camera includes an image sensor having a substrate having an array of pixels each pixel having a photosensitive region, and the array of pixels includes a subset of at least two pixels; primary microlenses each spanning or substantially spanning each pixel of the subset; and one or more secondary microlenses positioned between the primary microlenses and the plurality of pixels in which each secondary microlens spans one of the subset of pixels so that incident light that passes through the primary microlenses and secondary microlenses are directed onto a center portion or substantially a center portion of the photosensitive regions.

### CROSS REFERENCE TO RELATED APPLICATION

Reference is made to and priority claimed from U.S. Provisional Application Ser. No. 60/889,326, filed Feb. 12, 2007, entitled MICROLENSES FOR ASYMMETRIC PIXELS.

### FIELD OF THE INVENTION

The invention relates generally to the field of image sensors and, more particularly, to providing microlenses that correct optical irregularities of pixels.

### BACKGROUND OF THE INVENTION

The use of microlenses to focus light onto the photosensitive region of a pixel has a long history going back to U.S. Pat. No. 4,667,092. FIG. 1 illustrates the prior art use of microlenses on an active pixel (CMOS) sensor. A CMOS active sensor is shown only as one example of the type of image sensors using microlenses. Microlenses are also used on charge-coupled devices (CCD). The prior art pixel 101 shown in FIG. 1 has microlenses 135 that focus light rays 145 through color filter materials 125 and 130 to a focal point 140 within the photosensitive region 100. Metal layers 110 are used to carry voltage signals to the pixels. FIG. 2 shows an aerial view of an array of square microlenses 135 covering an array of square pixels.

Enhancements to microlens structures include variations of adding a secondary microlens 151, as shown in FIG. 1, to further improve the focusing of light. The secondary lens 151 is used for reducing smear, widening light collection angles, or increasing light collection efficiency. Examples of such improvements can be found in U.S. Pat. Nos. 5,371,397, 5,711,890, 5,734,190, 6,188,094, 6,255,640, and 7,019,373.

There is an unsolved problem related to microlenses occurring often on pixels smaller than 2.5 μm. The layout of gates and wires within the small pixel is irregular. This irregularity is shown in FIG. 1 where two photosensitive regions 100 are close together and the next pair of photosensitive regions is separated by a larger distance. This causes the focal point 140 to be close to the edge of the photosensitive regions 100. Thus, there is needed an invention that will place the focal point of a microlens in the center of the photosensitive region of irregular pixels.

### SUMMARY OF THE INVENTION

The present invention is directed to overcoming one or more of the problems set forth above. Briefly summarized, according to one aspect of the present invention, the invention resides in an image sensor comprising a substrate having an array of pixels each pixel having a photosensitive region, and the array of pixels includes a subset of at least two pixels; primary microlenses each spanning or substantially spanning each pixel of the subset; and one or more secondary microlenses positioned between the primary microlenses and the plurality of pixels in which each secondary microlens spans one of the subset of pixels so that incident light that passes through the primary microlenses and secondary microlenses are directed onto a center portion or substantially a center portion of the photosensitive regions.

The above and other objects of the present invention will become more apparent when taken in conjunction with the following description and drawings wherein identical reference numerals have been used, where possible, to designate identical elements that are common to the figures.

### ADVANTAGEOUS EFFECT OF THE INVENTION

The invention corrects optical irregularities of image sensor pixels.

### BRIEF DESCRIPTION OF THE DRAWINGS

FIG. 1 is a prior art image sensor with microlenses focusing light on irregular spaced photodiodes;

FIG. 2 is an aerial view of an array of prior art microlenses;

FIG. 3 is a cross-sectional view of the present invention employing secondary lenses spanning two pixels to correct irregularities;

FIG. 4 is an aerial view of the secondary lenses of the present invention that have a cylindrical shape;

FIG. 5 shows photoresponse curves vs. angle comparing the present invention to prior art;

FIG. 6 is an aerial view of the secondary lenses of the present invention that have a square shape spanning 4 pixels;

FIG. 7 is a cross-sectional view of the present invention employing secondary lenses spanning three pixels to correct irregularities; and

FIG. 8 is a camera imaging system having an image sensor of the present invention using a pixel with secondary lenses correcting optical irregularities of pixels.

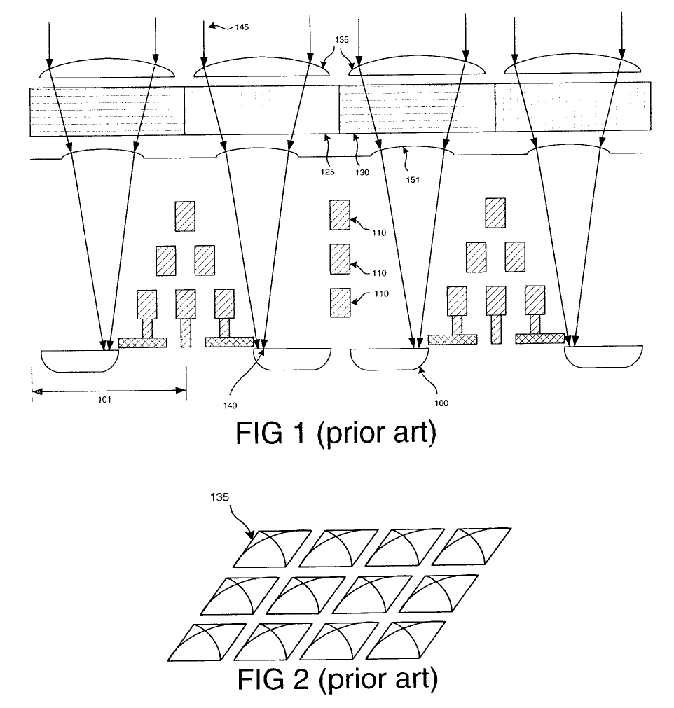

### DETAILED DESCRIPTION OF THE INVENTION

Before discussing the present invention in detail, it is instructive to note that the present invention can be applied to either charge-coupled device (CCD) type image sensors, active pixel type image sensors, CMOS active pixel image sensors or any other type of image sensor where the photoactive region of the pixel is not centered within the pixel.

Active pixel sensor refers to an active electrical element within the pixel, other than transistors functioning as switches. For example, the floating diffusion or amplifier is active elements. CMOS refers to complementary metal oxide silicon type electrical components such as transistors which are associated with the pixel, but typically not in the pixel, and which are formed when the source/drain of a transistor is of one dopant type (for example n-type) and its mated transistor is of the opposite dopant type (for example p-type). CMOS devices include some advantages one of which is it consumes less power.

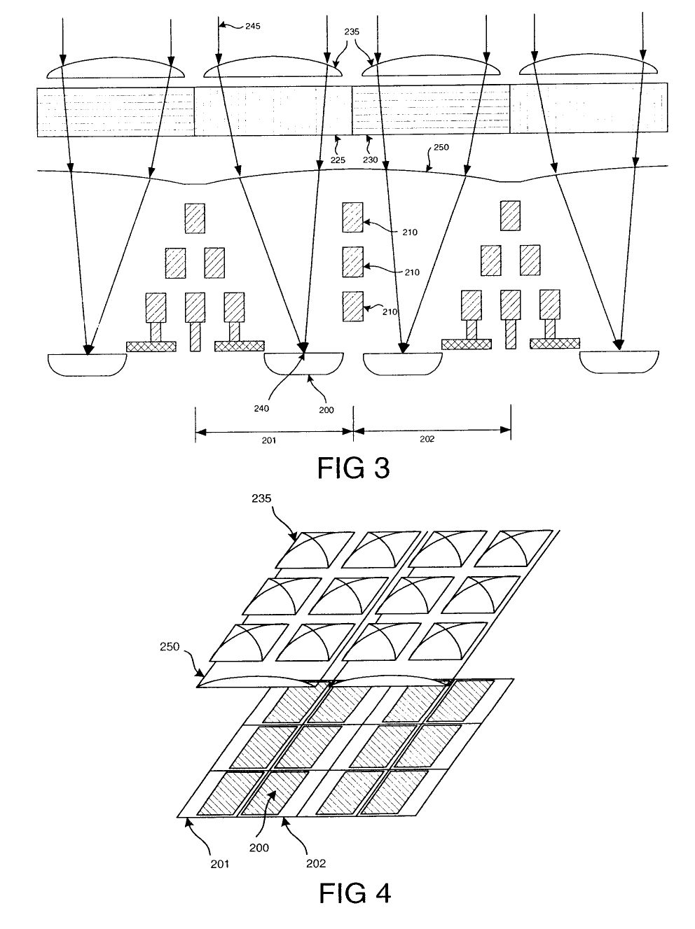

FIG. 3 shows a cross section of four pixels from an image sensor array. The fundamental unit cell of the pixel 201 is mirror imaged at pixel 202. These mirror imaged pairs of pixels are repeated across the entire image sensor array. The pixel 201 has a photosensitive region 200 (preferably a photodiode or pinned photodiode in the case of an active or CMOS image sensor or a photodiode in the case of a CCD) which is not in the center of the pixel. There are metal wiring layers 210 to transmit voltage signals to and from each pixel in the image sensor array. The top microlenses 235 focus light rays 245 through color filters 225 and 230. Just below the color filters 225 and 230 is a secondary microlens 250 with a cylindrical cross-section that spans the width of two pixels. The cylindrical secondary microlens 250 is positioned with its center located approximately over the region of shortest distance between two photosensitive regions 200. The secondary microlens 250 uses optical refraction to divert the focal point 240 to the center of the photosensitive region 200. The secondary microlens 250 may be of a convex or concave shape depending on the relative values of the material index of refraction above and below the secondary microlens surface. The secondary microlens 250 may also be manufactured out of organic or inorganic materials. A common choice would be to form the secondary microlens 250 in the top nitride passivation layer and then coat that nitride passivation layer with an organic material with a lower index of refraction. The secondary microlens 250 does not have to be below the color filters 225 and 230, and can even be located among (i.e., between or under) the wiring layers 210.

FIG. 4 shows an aerial view of 12 pixels. The cylindrical secondary microlenses 250 are oriented with their axis perpendicular to the direction of mirror asymmetry of the pixels 201 and 202. The wiring layers 210 have been omitted from FIG. 4 for clarity.

The advantageous effect of the present invention is shown in FIG. 5. Curve 195 is the signal output of the prior art. The irregular spacing of photosensitive regions in the prior art pixel forces the peak of the signal curve to favor light rays at an angle. By refracting light rays to the center of the photosensitive region the secondary cylindrical lens produces an output signal curve 190 that has its maximum for normally incident light rays.

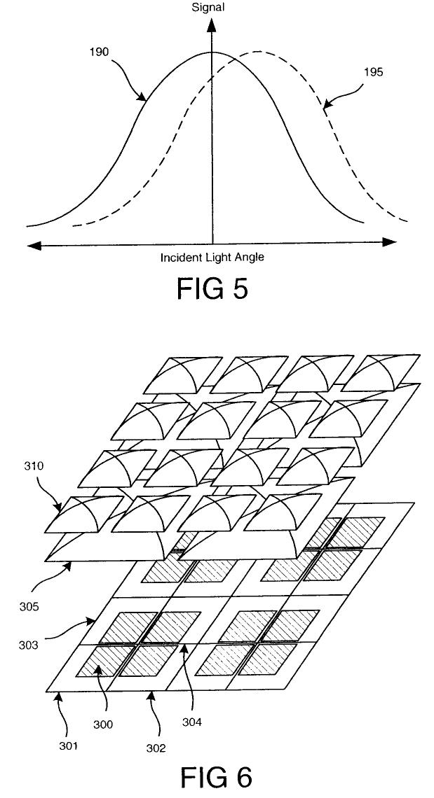

The benefit of the present invention is not due to the fact that a cylindrical secondary lens is used. The benefit arises from the secondary lens spanning the width of two pixels. An example of a non-cylindrical lens is shown in FIG. 6. The photosensitive region 300 is located near the corner of the pixel 301. Pixel 302 is a horizontal mirror image of pixel 301. Pixels 303 and 304 are vertical mirror images of the pixels 301 and 302. This arrangement of pixels requires a secondary microlens 305 capable of refracting the light of a group of four pixels. This is accomplished by making the secondary microlens 305 a square shape spanning a 2 by 2 unit cell of pixels. A rectangular shape secondary microlens may also be used if the photosensitive regions or pixels are rectangular. An array of microlenses 310 is positioned on top of the pixel array with one microlens 310 for each pixel.

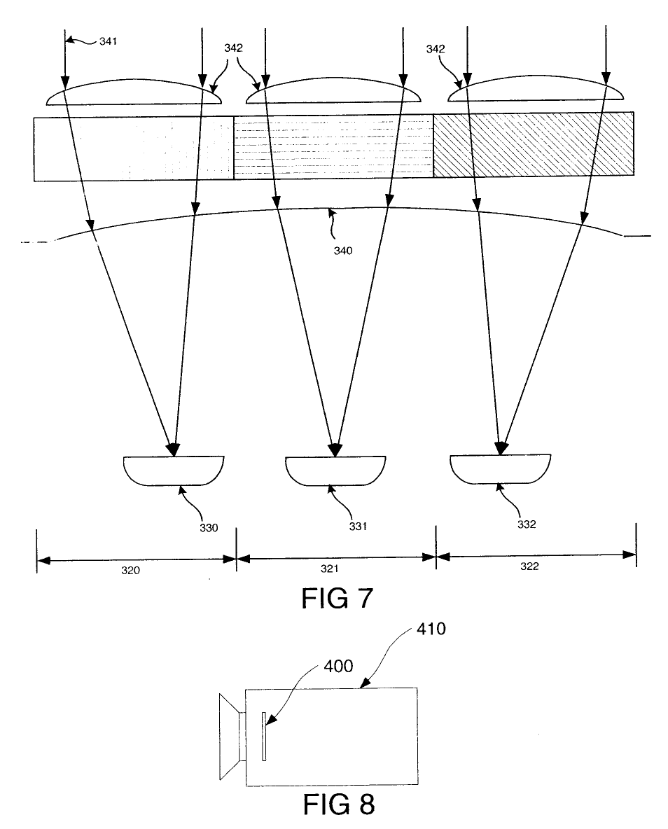

The present invention is not limited to a secondary microlens spanning just two pixels. FIG. 7 shows a subset of an array of pixels consisting of a repeating unit cell of pixels 320, 321, and 322. Pixel 321 has its photosensitive region 331 centered within the pixel. Pixel 320 has its photosensitive region 330 located right of center towards pixel 331. Pixel 322 has its photosensitive region 332 located left of center towards pixel 331. This irregular spacing of photosensitive regions can be corrected by secondary microlens 340 spanning the three pixel repeating unit cell. The secondary microlens 340 refracts light rays 341 so the focal spots of the top microlenses 342 are positioned in the centers of the photosensitive regions. The repeating unit cell may consist of three pixels for which a cylindrical-shaped secondary microlens is appropriate. If the repeating unit cell consists of a sub-array of 3×3 pixels, then a square secondary microlens spanning all 9 pixels is the best choice.

It is considered obvious that if the camera lens focuses light upon the image sensor array at an angle other than normal (0 degrees), then it is possible to modify the present invention by offsetting the optical stack of each pixel to match the camera lens angle.

FIG. 8 illustrates a digital camera 410 using an image sensor 400 that has an array of irregular pixels using secondary microlenses of the present invention spanning more than one pixel.

The invention has been described with reference to a preferred embodiment. However, it will be appreciated that a person of ordinary skill in the art can effect variations and modifications without departing from the scope of the invention.

### PARTS LIST

100 photosensitive region
101 pixel
110 metal wiring layers
125 color filter material
130 color filter material
135 microlens
140 focal point
145 light rays
151 secondary microlens
190 output signal curve
195 signal output curve of the prior art
200 photosensitive region
201 unit cell of pixels
202 pixel
210 metal wiring layers
225 color filter
230 color filter
235 top microlenses
240 focal point
245 light rays
250 microlens
300 photosensitive region
301 pixel
302 pixel
303 pixel
304 pixel
305 secondary microlens
310 array of microlenses
320 unit cell of pixels
321 unit cell of pixels
322 unit cell of pixels
330 photosensitive region
331 photosensitive region
332 photosensitive region
340 secondary microlens
341 light rays
342 top microlenses
400 image sensor
410 digital camera

What is claimed is:

1. An image sensor comprising:
(a) a substrate having an array of pixels each pixel having a photosensitive region, and the array of pixels includes a subset of at least two pixels;
(b) primary microlenses each spanning or substantially spanning each pixel of the subset; and
(c) one or more secondary microlenses positioned between the primary microlenses and the plurality of pixels in which each secondary microlens spans or substantially spans one of the subset of pixels so that incident light that passes through the primary microlenses and secondary microlenses are directed onto a center portion or substantially a center portion of the photosensitive regions.

2. The image sensor as in claim 1 wherein one or more of the photosensitive regions are not in a center of its pixel.

3. The image sensor as in claim 1, wherein the subset is a 2×1 array of pixels.

4. The image sensor as in claim 1, wherein the secondary microlens is shaped as a cylindrical cross-section.

5. The image sensor as in claim 1, wherein the subset is a 2×2 array of pixels.

6. The image sensor as in claim 1, wherein the subset is a 3×3 array of pixels.

7. The image sensor as in claim 1, wherein the secondary microlenses are either concave or convex.

8. The image sensor as in claim 1, wherein the photosensitive region is a photodiode.

9. The image sensor as in claim 1, wherein the photosensitive region is a pinned photodiode.

10. The image sensor as in claim 5, wherein each photosensitive region in the 2×2 array is positioned adjacent a corner of its respective pixel.

11. A digital camera comprising:
an image sensor comprising:
(a) a substrate having an array of pixels each pixel having a photosensitive region, and the array of pixels includes a subset of at least two pixels;
(b) primary microlenses each spanning or substantially spanning each pixel of the subset; and
(c) one or more secondary microlenses positioned between the primary microlenses and the plurality of pixels in which each secondary microlens spans or substantially spans one of the subset of pixels so that incident light that passes through the primary microlenses and secondary microlenses are directed onto a center portion or substantially a center portion of the photosensitive regions.

12. The digital camera as in claim 11 wherein one or more of the photosensitive regions are not in a center of its pixel.

13. The digital camera as in claim 11, wherein the subset is a 2×1 array of pixels.

14. The digital camera as in claim 11, wherein the secondary microlens is shaped as a cylindrical cross-section.

15. The digital camera as in claim 11, wherein the subset is a 2×2 array of pixels.

16. The digital camera as in claim 11, wherein the subset is a 3×3 array of pixels.

17. The digital camera as in claim 11, wherein the secondary microlenses are either concave or convex.

18. The digital camera as in claim 11, wherein the photosensitive region is a photodiode.

19. The digital camera as in claim 11, wherein the photosensitive region is a pinned photodiode.

20. The digital camera as in claim 15, wherein each photosensitive region in the 2×2 array is positioned adjacent a corner of its respective pixel.
